(19) United States
(12) Patent Application Publication
(10) Pub. No.: US 2015/0179598 A1
(43) Pub. Date: Jun. 25, 2015

(54) FLIP-CHIP PACKAGING STRUCTURE

(71) Applicant: Siliconware Precision Industries Co., Ltd, Taichung (TW)

(72) Inventors: Shih-Chao Chiu, Taichung (TW); Liang-yi Hung, Taichung (TW)

(73) Assignee: Siliconware Precision Industries Co., Ltd, Taichung (TW)

(21) Appl. No.: 14/183,896

(22) Filed: Feb. 19, 2014

(30) Foreign Application Priority Data
Dec. 24, 2013 (TW) 102147925

(51) Int. Cl. H01L 23/00; H01L 23/28

(52) U.S. Cl. CPC H01L 24/17; H01L 23/28; H01L 2924/01029; H01L 2924/01079; H01L 2924/0132; H01L 2924/37001; H01L 2924/18161

(57) ABSTRACT

A flip-chip packaging structure is provided, which includes: a packaging substrate having a substrate body and a circuit layer formed on the substrate body, wherein the circuit layer has a plurality of conductive pads embedded in the substrate body and exposed from a surface of the substrate body; and a chip disposed on and electrically connected to the packaging substrate through a plurality of conductive elements, wherein the conductive elements and the exposed portions of the conductive pads have a width ratio in a range of 0.7 to 1.3, thereby improving the product yield and reliability.

### BACKGROUND OF THE INVENTION

1. Field of the Invention

The present invention relates to flip-chip packaging structures, and more particularly, to a flip-chip packaging structure with conductive elements and conductive pads having a width ratio in a certain range.

2. Description of Related Art

To meet demands for lighter, thinner, smaller and multi-functional electronic products, various packaging technologies have been developed. Therein, flip-chip packaging technologies are mainstream technologies.

In a conventional flip-chip package, conductive bumps of a chip are bonded to conductive pads of a packaging substrate through a reflow process. But in the conventional flip-chip package, the width of the conductive pads of the packaging substrate does not match the width of the conductive bumps. Therefore, non-wetting easily occurs between the conductive pads and the conductive bumps.

FIG. 1 is a schematic cross-sectional view of a conventional flip-chip packaging structure. Referring to FIG. 1, a plurality of conductive elements 101 are formed on a surface of a chip 10 and each has a width W. The conductive elements 101 here are conductive bumps, and a solder material 103 is further formed on the conductive elements 101. A plurality of conductive pads 2001 are embedded in a packaging substrate 20 and exposed from first openings 2011 of a surface of the packaging substrate 20. Each of the first openings 2011 has a width W′.

When the chip 10 is disposed on the packaging substrate 20, if the width W of the conductive elements 101 does not match the width W′ of the first openings 2011, for example, if the width W′ of the first openings 2011 is significantly less than the width W of the conductive elements 101, the solder material 103 cannot enter or fill the first openings 2011. As such, the conductive elements 101 cannot be electrically connected to the conductive pads 2001, or bonding between the conductive elements 101 and the conductive pads 2001 has poor mechanical or electrical performance (for example, short circuit or increased resistance), thereby adversely affecting the product yield of the flip-chip packaging structure.

Therefore, how to overcome the above-described drawbacks has become critical.

### SUMMARY OF THE INVENTION

In view of the above-described drawbacks, the present invention provides a flip-chip packaging structure, which comprises: a packaging substrate having a substrate body and a circuit layer formed on the substrate body, wherein the circuit layer has a plurality of conductive pads embedded in the substrate body and exposed from a surface of the substrate body; and a chip disposed on and electrically connected to the packaging substrate through a plurality of conductive elements, wherein the conductive elements and the exposed portions of the conductive pads have a width ratio in a range of 0.7 to 1.3.

The conductive elements can be formed on a surface of the chip. The flip-chip packaging structure can further comprise a solder material formed between the conductive elements and the conductive pads for electrically connecting the conductive elements and the conductive pads.

Therefore, through computer calculation and experiment, the present invention provides a certain design rule for the width ratio between the conductive elements and the exposed portions of the conductive pads. As such, the present invention overcomes the conventional non-wetting problem and improves the bonding yield and quality between the packaging substrate and the chip.

### BRIEF DESCRIPTION OF DRAWINGS

FIG. 1 is a schematic cross-sectional view showing bonding between a chip and a packaging substrate of a conventional flip-chip packaging structure;

FIG. 2 is a schematic cross-sectional view of a chip of a flip-chip packaging structure of the present invention;

FIG. 3 is a schematic cross-sectional view of a packaging substrate of the flip-chip packaging structure of the present invention;

FIG. 3′ is a schematic cross-sectional view of a packaging substrate of the flip-chip packaging structure according to another embodiment of the present invention; and

FIG. 4 is a schematic cross-sectional view of the flip-chip packaging structure of the present invention.

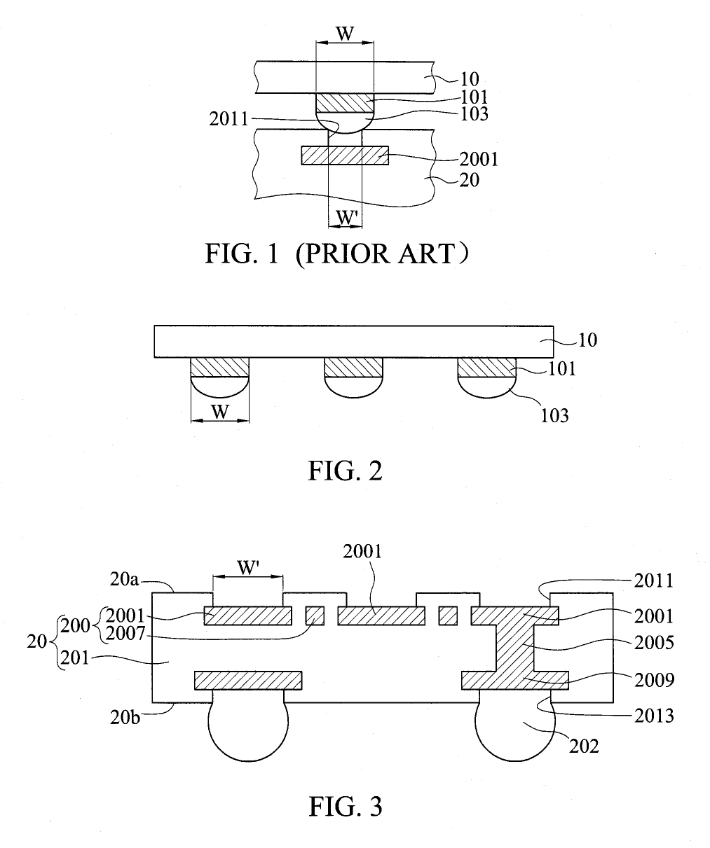

### DETAILED DESCRIPTION OF PREFERRED EMBODIMENTS

The following illustrative embodiments are provided to illustrate the disclosure of the present invention, these and other advantages and effects can be apparent to those in the art after reading this specification.

It should be noted that all the drawings are not intended to limit the present invention. Various modifications and variations can be made without departing from the spirit of the present invention.

FIG. 2 is a schematic cross-sectional view of a chip 10 of a flip-chip packaging structure 1 of the present invention. Referring to FIG. 2, a plurality of conductive elements 101 are formed on a surface of the chip 10 and each has a width W. The conductive elements 101 can be, but not limited to, conductive bumps made of gold, copper or tin-lead alloy. A solder material 103 is further formed on the conductive elements 101.

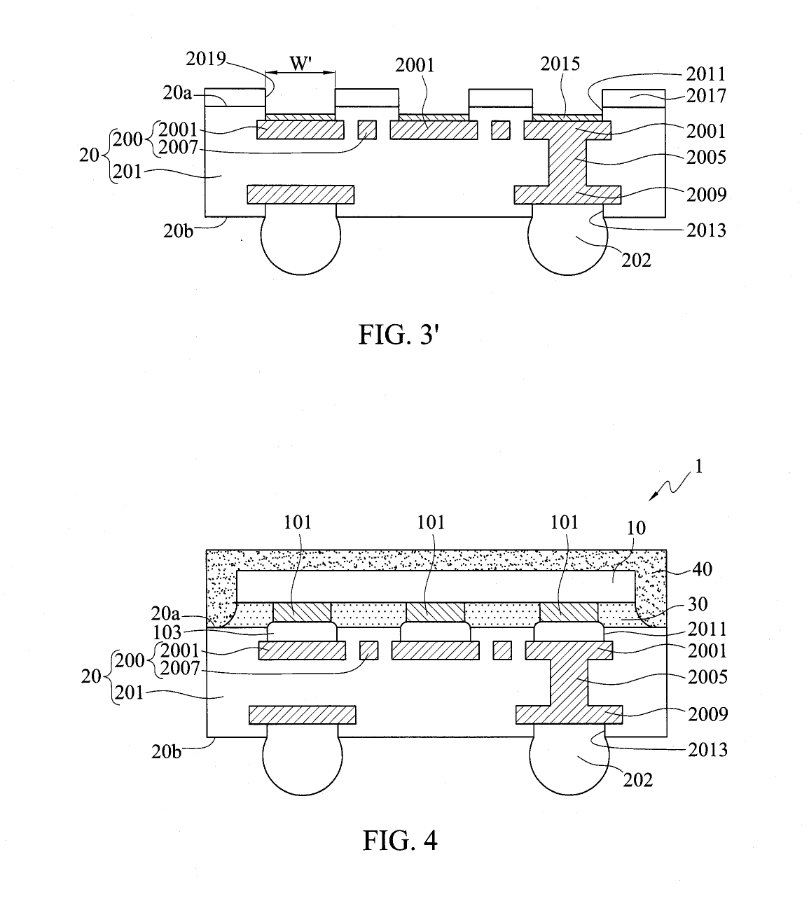

FIG. 3 is a schematic cross-sectional view of a packaging substrate 20 of the flip-chip packaging structure 1. The packaging substrate 20 has opposite first and second surfaces 20a, 20b. The packaging substrate 20 includes a substrate body 201, a circuit layer 200 formed on the substrate body 201, a plurality of conductive through holes 2005 penetrating the substrate body 201, and a plurality of conductive pads 2009 connected to the conductive through holes 2005. The circuit layer 200 has a plurality of conductive pads 2001 embedded in the substrate body 201 and exposed from the first surface 20a of the substrate body 201. The substrate body 201 can be made of single or multiple layers of dielectric material having the circuit layer 200 embedded therein. For example, the circuit layer 200 is formed on a first dielectric layer, and a second dielectric layer is further formed on the first dielectric layer and the circuit layer 200 and has a plurality of openings for exposing the conductive pads 2001. In an alternative embodiment, the circuit layer 200 is embedded in a single dielectric layer and the conductive pads 2001 are exposed from a surface of the single dielectric layer. Further, the circuit layer 200 can include a plurality of circuits 2007 electrically connected to the conductive pads 2001.

The first surface 20a of the substrate body 201 has a plurality of first openings 2011, and the second surface 20b of the substrate body 201 has a plurality of second openings 2013. Each of the first openings 2011 has a width W′. The ratio of the width W of the conductive elements 101 to the width W′ of the first openings 2011 is in a range of 0.7 to 1.3. The conductive pads 2001 are exposed from the first surface 20a through the first openings 2011.

The conductive through holes 2005 are formed to electrically connect the circuit layer 200 and the conductive pads 2009.

The conductive pads 2009 are embedded in the substrate body 201 and exposed from the second surface 20b of the substrate body 201 through the second openings 2013.

The circuits 2007 can be embedded in the first surface 20a of the substrate body 201. The conductive pads 2001, the conductive through holes 2005 and the circuits 2007 can be made of copper or copper alloy.

Further, a plurality of conductive elements 202, such as solder balls or conductive bumps, can be formed in the second openings 2013 and electrically connected to the conductive pads 2009.

FIG. 3′ is a schematic cross-sectional view of the packaging substrate 20 according to another embodiment of the present invention. In the present embodiment, the packaging substrate 20 further has a surface processing layer 2015 and an insulating layer 2017.

The surface processing layer 2015 is formed on the conductive pads 2001 in the first openings 2011. The insulating layer 2017, such as a solder mask layer, is formed on the first surface 20a of the substrate body 201 and has a plurality of openings 2019 for exposing the conductive pads 2001. Further, the insulating layer 2017 can be formed on the second surface 20b of the substrate body 201 and have a plurality of openings corresponding in position to the second openings 2013 (not shown).

FIG. 4 is a schematic cross-sectional view of the flip-chip packaging structure 1 of the present invention. The chip 10 of FIG. 2 is flip-chip disposed on the packaging substrate 20 of FIG. 3 through the solder material 103 on the conductive elements 101. In particular, through a reflow process, the solder material 103 is melted and solidified between the conductive elements 101 and the conductive pads 2001 for electrically connecting the conductive elements 101 and the conductive pads 2001. Since the ratio of the width W of the conductive elements 101 to the width W′ of the conductive pads 2001 is in a range of 0.7 to 1.3, the present invention overcomes the conventional non-wetting problem and ensures a high thermal stability in a thermal cycling test.

The flip-chip packaging structure 1 further has an underfill 30 formed between the chip 10 and the packaging substrate 20 for encapsulating the conductive elements 101, and an encapsulant 40 formed on the packaging substrate 20 for encapsulating the chip 10.

In another embodiment, the conductive elements can be formed on the conductive pads of the packaging substrate instead of the chip.

According to the present invention, the width ratio between the conductive elements 101 and the exposed portions of the conductive pads 2001 is designed to be in a range of 0.7 to 1.3 so as to overcome the conventional non-wetting problem and ensure a high thermal stability in a thermal cycling test, thereby improving the flip-chip bonding yield and product reliability.

The above-described descriptions of the detailed embodiments are only to illustrate the preferred implementation according to the present invention, and it is not to limit the scope of the present invention. Accordingly, all modifications and variations completed by those with ordinary skill in the art should fall within the scope of present invention defined by the appended claims.

What is claimed is:

1. A flip-chip packaging structure, comprising:
a packaging substrate having a substrate body and a circuit layer formed on the substrate body, wherein the circuit layer has a plurality of conductive pads embedded in the substrate body and exposed from a surface of the substrate body; and
a chip disposed on and electrically connected to the packaging substrate through a plurality of conductive elements, wherein the conductive elements and the exposed portions of the conductive pads have a width ratio in a range of 0.7 to 1.3.

2. The structure of claim 1, wherein the conductive elements are formed on a surface of the chip.

3. The structure of claim 2, further comprising a solder material formed between the conductive elements and the conductive pads for electrically connecting the conductive elements and the conductive pads.

4. The structure of claim 1, wherein the circuit layer further has a plurality of circuits electrically connected to the conductive pads.

5. The structure of claim 1, further comprising an insulating layer formed on the surface of the substrate body and having a plurality of openings exposing the conductive pads.

6. The structure of claim 1, wherein the conductive elements are conductive bumps.

7. The structure of claim 6, wherein the conductive bumps are made of gold, copper or tin-lead alloy.

8. The structure of claim 1, wherein the circuit layer is made of copper.

9. The structure of claim 1, further comprising a surface processing layer formed on the conductive pads.

10. The structure of claim 1, further comprising an underfill formed between the chip and the packaging substrate for encapsulating the conductive elements.

11. The structure of claim 1, further comprising an encapsulant formed on the packaging substrate for encapsulating the chip.

12. The structure of claim 1, wherein the conductive elements are formed on the conductive pads.
